(19) United States
(12) Patent Application Publication
(10) Pub. No.: US 2010/0211222 A1
(43) Pub. Date: Aug. 19, 2010

(54) METHOD AND APPARATUS FOR COMPREHENSIVE ENERGY MEASUREMENT AND ANALYSIS OF A BUILDING

(76) Inventor: Michel GHOSN, Sugar Land, TX (US)

Correspondence Address: Keith C. Rawlins, Attorney & Counselor at Law, 12 Greenway Plaza, Suite 1100, Houston, TX, 77046, US

(21) Appl. No.: 12/631,975

(22) Filed: Dec. 7, 2009

Related U.S. Application Data
(60) Provisional application No. 61/153,877, filed on Feb. 19, 2009.

(51) Int. Cl. G06F 1/32; G05D 23/19; G01R 21/00; G01K 13/00; G01R 19/00; G06F 19/00

(52) U.S. Cl. 700/276; 702/61; 702/136; 324/76.11; 700/286; 702/182

(57) ABSTRACT

An energy monitoring and analysis system for a building includes a logging unit, a processing unit, temperature sensors that read the temperatures inside and outside the building, electric current sensors that read electric currents in all independent electric connections at the main connection panel of the building, and other types of sensors such as those related to natural gas flow. The logging unit periodically collects the data from all the sensors and transmits the data to the processing unit. The processing unit analyzes the data using highly sophisticated algorithms, extracts various parameters, profiles the electric energy usage, identifies potential problems with energy transfer and use, and lists recommendations for corrective actions. The processing unit analyzes data of the building, an HVAC system associated with the building, and consuming devices associated with the building.

### CROSS-REFERENCE TO RELATED APPLICATIONS

The present application claims priority to U.S. Provisional Application No. 61/153,877, filed by the present inventor on Feb. 19, 2009.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The disclosed method and apparatus relate to the energy efficiency of buildings. Particularly, the disclosed apparatus and method relate to the recordation, calculation, and communication of the energy efficiency of the construction of the building, the HVAC system of the building, the electrical equipment in the building, and the usage of the building and equipment by occupants of the building.

2. Description of Related Art

Buildings consume energy based on the activities of occupants thereof, who determine the extent of usage of electrical equipment associated with the building. Of course, buildings today can have myriad areas that are temperature-controlled by multiple HVAC systems. The simplest of buildings has one area and one HVAC system controlling the temperature of the area. The HVAC of this building is responsible for controlling the temperature of the area. The temperature of the area is affected by any type of heating or cooling source associated with the building, such as lights, computers, the components of the HVAC system, TVs, stoves, ovens, etc. Most of these sources are sources of heat.

In the past, various patents have issued relating to apparatus and methods that record the electricity usage of a building, analyze the usage, and report the analysis. For example, U.S. Pat. No. 5,544,036, U.S. Pat. No. 5,798,945, U.S. Pat. No. 5,924,486, U.S. Pat. No. 6,216,956, U.S. Pat. No. 6,385,510, U.S. Pat. No. 6,789,739, U.S. Pat. Nos. 6,874,691, 7,349,824, and U.S. Pat. No. 7,451,017.

A problem associated with prior art is that prior art does not account for inefficient equipment. For example, it is not a complete benefit for an occupant of a building to switch electricity providers while using largely inefficient equipment that counterbalances any cost savings generating by switching to the new provider. Thus, there is a need to account for costs of the devices of a building in order to maximize cost savings for electricity.

Another problem associated with prior art is that prior art does not account for the thermal characteristics of the building itself. For example, it is not a complete benefit for the occupant of a building to improve the controls of the heating and cooling system(s) while ignoring the heat loss/gain through the building shell/foundations. Thus, there is a need for accounting not only for the thermal characteristics of heating and cooling system(s), but for thermal characteristics of the building in which the heating and cooling system(s) reside.

Another problem associated with prior art is that prior art does not account for inefficient equipment that performs ideally. For example, a specialized electronic apparatus that records the mechanical and electrical operation characteristics of heating and cooling equipment to determine the performance of the equipment based on predefined ideal performance charts is not a complete benefit for the occupant of a building if the performance of the equipment conforms to the predefined ideal performance while the equipment is undersized for the task required in the building, resulting in an overload of the equipment and an ultimate increase in the total cost of ownership of the equipment because of increased risk of failure and repair of said equipment. Thus, there is a need to recognize when equipment is inefficient in energy usage even though the equipment performs ideally according to predefined performance data.

All the previous art attempts fail to provide comprehensive analysis reports correlating the electricity consumption with the occupant usage habits of electrical energy and with the thermal characteristics for building and enclosed structures to form an overall button line cost savings for the occupants. Thus, there is a need for communicating a comprehensive performance report for the building, the HVAC system(s) of the building, and the electric devices used in the building to people associated with the building so as to optimize energy performance.

It is an object of the disclosed method of apparatus to increase the energy efficiency of a building.

It is another object of the disclosed method and apparatus to increase the energy efficiency of electrical equipment associated with the building.

It is another object of the disclosed method and apparatus to recognize equipment that is energy-inefficient even though performing ideally.

It is another object of the disclosed method and apparatus to log and analyze energy data associated with a building.

It is still another object of the disclosed method and apparatus to analyze energy data by gathering temperature and current data from a building and any associated electrical equipment.

It is another object of the disclosed method and apparatus to communicate analyzed energy data to a user of the method and/or apparatus as a comprehensive energy report.

It is another object of the disclosed apparatus and method to provide an apparatus that is small, inexpensive, and easy to install in a building.

The objects of the disclosed invention are not limited to those mentioned above. These and other objects are made apparent by the specification, claims, and drawings.

### SUMMARY OF THE INVENTION

The present invention is a system, method, and apparatus to provide a low cost, simple, and comprehensive analysis of the energy usage and parameters of a building. The invention involves: (a) collecting and analyzing the occupant pattern's habit of electricity usage to reduce consumption without affecting the lifestyle or the comfort of the occupant; (b) collecting and analyzing the temperature from inside and outside the building to quantitatively measure the thermal characteristics of the building (composite heat transfer coefficient and specific heat capacity) to indicate the corrective actions leading to a reduction heat loss and therefore reduce energy cost; and (c) collecting and analyzing the electricity consumption of all area lines connecting to the main electric panel of the building so as to identify: i) abnormal operations such as an inadequate heating or cooling system, unexpected cycling of an appliance such as a refrigerator, a near-tripping overloaded electric breaker; and ii) optimum areas candidate to be supplied by an alternative source of electrical energy with the least amount of electricity storage units.

The apparatus comprises: a) a specialized electronic device that records utility power consumption on the individual electric conductors feeds connected to the main electric grid panel, records inside and outside temperatures, communicates the records to a remote processor; and (b) a processing device that utilizes specialized algorithms to calculate thermal characteristics of building structures, heating and cooling system operating characteristics, and electrical energy usage of the building. The apparatus can recommend solutions to improve energy conservation. The processor creates reports and publishes the reports through email, mail, and or posts it on the web (local PC and/or www). A current sensor is also provided.

### BRIEF DESCRIPTION OF THE SEVERAL VIEWS OF THE DRAWINGS

FIG. 1 shows the disclosed system for monitoring and analyzing energy of a building.

FIG. 2 shows a perspective view of the logging unit.

FIG. 3 shows an electronic functional block diagram of the logging unit.

FIG. 4 shows a flow diagram of the operating states of the logging unit.

FIG. 5 shows a flow diagram of the Record state of the logging unit.

FIG. 6 shows a flow diagram of the communication protocol of the logging unit.

FIGS. 7, 7a, 7b, 7c show the mechanical structure and electrical wiring of the disclosed current sensor.

FIG. 8 shows the block diagram of the temperature sensor.

FIG. 9 shows a perspective view of the processing unit connected to the logging unit.

FIG. 10 shows a block diagram of the processing unit connected to the logging unit.

FIG. 11 shows a flow diagram of the Transmit and Receive process of the processing application of the processing unit.

FIG. 12 shows a flow diagram of the Data Correction process of the processing application of the processing unit.

FIG. 13 shows a flow diagram of the Thermal Characteristics process of the processing application of the processing unit.

FIG. 14 shows an electric wiring diagram of the building heat equation.

FIG. 15 shows a table for containing data for the association of the current line with a specific heat release factor.

FIG. 16 shows a graph of the inside and outside temperature signals variations as a function of time correlated with the operation cycle of the heating and cooling system.

FIG. 17 shows a graph of the variation of the frequency characteristic and the duty cycle as a function of time.

FIG. 18 shows a table of the air temperature, density, and specific heat capacity for a range of most likely temperatures.

FIG. 19 shows a flow diagram of the Heating and Cooling System Analysis process of the processing application of the processing unit.

FIG. 20 shows a table for issue identification selection.

FIG. 21 shows a flow diagram of the Benchmarking process of the processing application of the processing unit.

FIG. 22 shows a user report generated by the processing application of the processing unit.

FIG. 23 shows a flow diagram of the Energy Use Profile process of the processing application of the processing unit.

FIG. 24 shows a flow diagram of the Warning process of the processing application of the processing unit.

FIG. 25 shows a flow diagram of the Alternative Energy process of the processing application of the processing unit.

FIG. 26 shows a flow diagram of the Reporting process of the processing application of the processing unit.

FIG. 27 shows a graph in the report generated by the processing application of processing unit that displays the electric energy usage for the consuming devices in a building versus time.

### DETAILED DESCRIPTION OF THE PREFERRED EMBODIMENT(S)

Referring to FIG. 1, there is shown a schematic diagram of a preferred embodiment of the disclosed system 100. The system 100 has a logging unit 1 connected to temperature sensors 6, 7, 8 and current sensors 11. The logging unit 1 collects, stores, and transmits the readings of the sensors 6, 7, 8, and 11. In FIG. 1, the logging unit 1 is an electronic apparatus that connects to temperature sensor 6 over wire 2 to measure the temperature outside building 9. The logging unit 1 connects to temperature sensor 7 over wire 3 to measure the inside temperature. The logging unit 1 connects to temperature sensor 8 over wireless radio to measure the temperature inside building 9. The logging unit 1 connects to current sensors 11 over wire 4 to measure, in non-invasive mode, the electric current running in each wire feed 12 of the main power supply line 10 the building structure 9. The wire feed 12 is also connected to the electric power line 13 of an electricity provider. Generally, each wire feed 12 provisions a group of outlets.

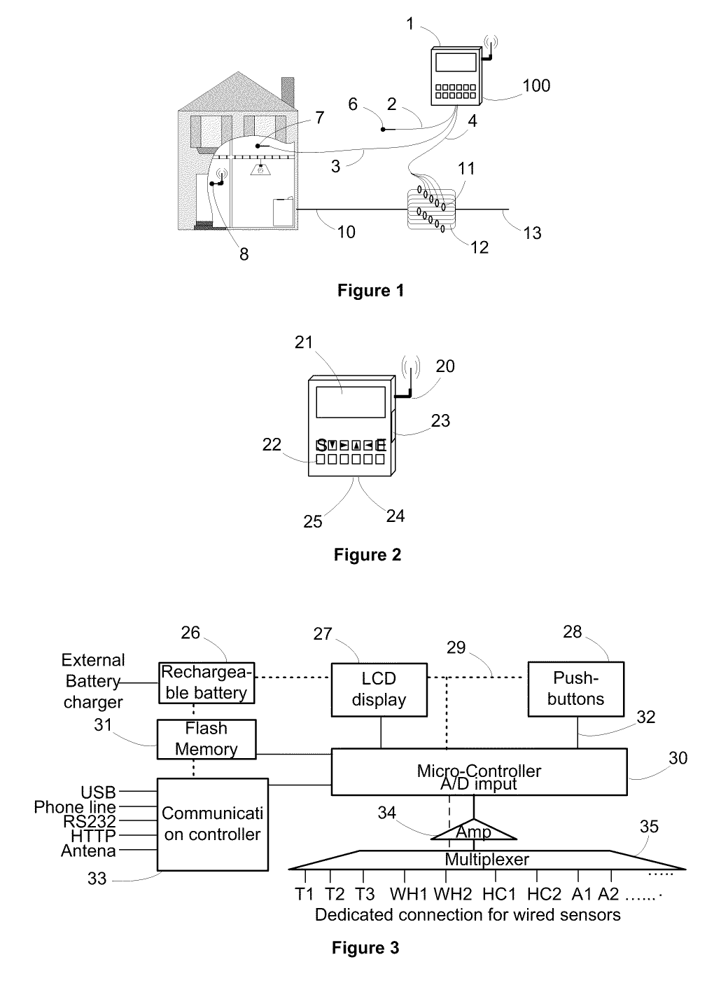

Referring to FIG. 2, there is shown a perspective view of a mechanical representation of the logging unit 1. The logging unit 1 has pushbuttons 22: a “Start” button that starts the logging, a “Stop” button that stops the logging, a “Transmit” button that transmits data from the logging unit 1, arrow buttons (up, down, right, left) that allow a user of the logging unit 1 to scroll over menus, and an “Enter” button that allows a user to select an item in one of the menus of the logging unit 1. The pushbuttons 22 are used to enter the order number before or after recording is complete. An initial order number is included in the logging unit 1 to enable the transmission to start. As shown in FIG. 2, the logging unit 1 has an LCD screen 21, a battery compartment 23, an antenna 20, and a socket location for connection to the sensors wires and communication lines.

Referring to FIG. 3, there is shown a schematic diagram of the electrical components of the logging unit 1. The components include a low-power micro-controller based with on-chip analog-to-digital converter 30 and on-onboard flash drive memory 31, a rechargeable battery 26, a LCD panel 27, push-buttons 28, and a communication controller 33 managing the communication connections (e.g. USB, phone line, RS232, HTTP, wireless). Sockets are wired to the multiplexer 35 to connect the wired sensors. The connections to wired sensors are labeled and dedicated entries for T1 (temperature sensor number 1, same as for T2, and T3) called temperature line entry, WH1 (water heater number 1, same as for WH2), HC1 (Heating and cooling system number 1, same as for HC2), A1 (area number 1, same as for the rest A2, up to the physical capacity limit of the logging unit sensor connections) called current line entries.

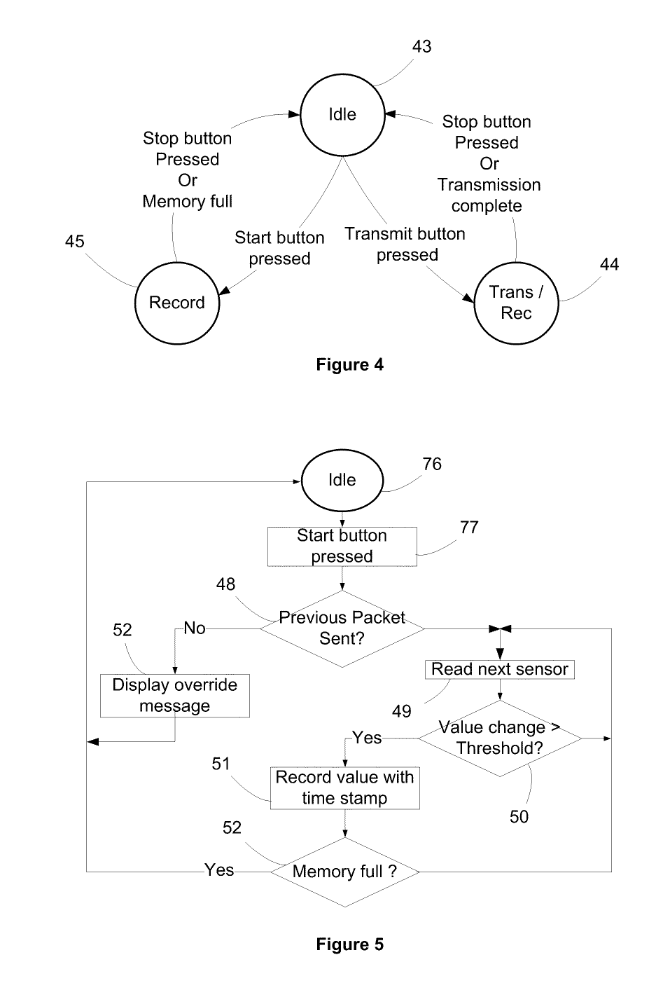

Referring to FIG. 4, there is shown a diagram of the operating states of the logging unit 1. There are three logical operating states: the Idle state 43, the Record state 45, and the Transmit/Receive state 44. Passing from one state to another is triggered by events, such as when pushbuttons of the logging unit 1 are pressed or when internal operation of the logging unit 1 is interrupted. FIG. 4 also shows that the move from Idle 43 state to Record state 45 is triggered by pressing the Start button.

Referring to FIG. 5, there is shown a process flow diagram of the Record state of the logging unit 1. If the previously stored data packet 48 was not transmitted, the application interrupts the flow by displaying an override message 52 on the LCD display and goes back to the Idle 46 state. In the case that the move is allowed, the first sensor is read 49. If the value of the sensor has changed by more than a predefined threshold 50 since the last read, then the new value is recorded with a timestamp 51. This operation repeats itself sequentially for all the sensors in the system until one of the following events occur: (a) the Stop button is pressed, or (b) the on-board memory 52 is full.

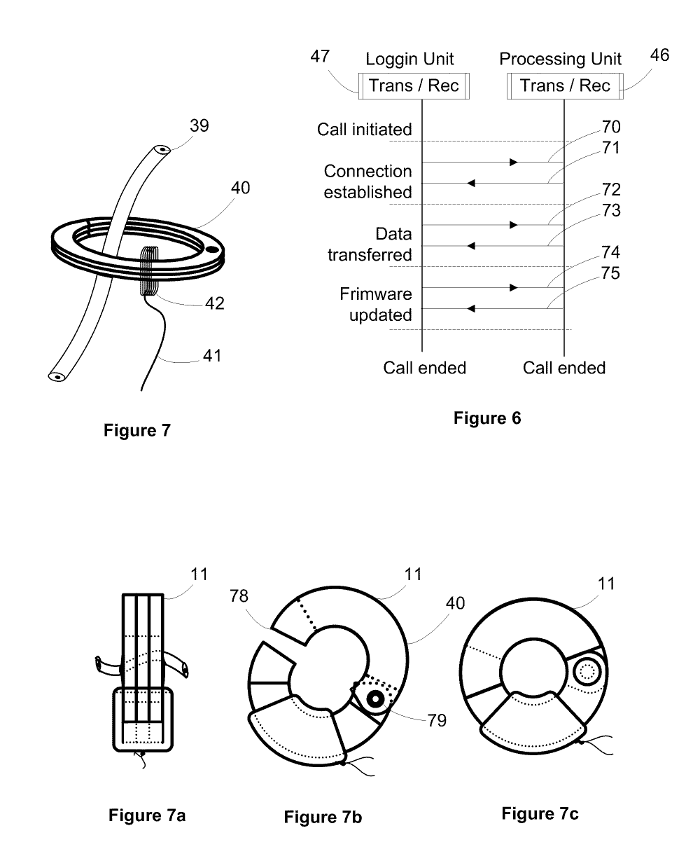

Referring to FIG. 6, there is shown the communication protocol of the logging unit 1 for moving from the Idle state to the Transmit/Receive 48 state after the Transmit button is pressed. The logging unit 1 initiates a call 70 established over the physical layer of the communication network to which the logging unit 1 is connected. For example, when the logging unit 1 is connected to a phone line, this layer dials a number and prepares for fax transmission negotiation. If the communication network is the Internet, this layer initiates File Transfer Protocol to a dedicated file server that is part of the processing unit, as is discussed below. The processing unit acknowledges 71 and passes on communication channel attributes to the logging unit 1. The logging unit 1 transmits the recorded data 72 and waits for the confirmation 73. If confirmation is received the logging unit 1 sends the request to update the firmware 74, and the processing unit complies with the upgrade packet 75.

Referring to FIG. 7, there is shown a perspective view of a preferred embodiment of a current sensor 11 used in the disclosed system 100. The current sensor 11 is connected to the logging unit 1. Each current sensor 11 of the system 100 senses a current value from electric wire 39 that supplies power to consuming devices inside and outside the building structure 9. A hinged bracket 40 is positioned around the electric wire 39 so that the passing electric current is measured. A coiled thin wire 42 is wrapped around the bracket 40 and positioned to receive the largest amount of magnetic flux generated by the main current of the wire 39. The magnetic flux induces a current in the coiled wire 42, and the induced current is conducted to the logging unit 1 through an electric wire 41, called sensor wire.

FIGS. 7a, 7b, and 7c show a side elevational view of the current sensor 11, a plan view of the current sensor 11 in an open position, and a plan view of the current sensor 11 in a closed position, respectively. The current sensor 11 has a hinged bracket 40. The hinged bracket has a first portion pivotally connected to a second portion. A hinge 79 ensures the first and second portions pivot with respect to one another. Each of the first portion and the second portion has a first arcuate piece, a second arcuate piece spaced from the first arcuate piece, a third arcuate piece positioned between the first arcuate piece and the second arcuate piece, and a coiled wire 42 wrapped around the hinged bracket 40. The third arcuate piece has an end 78 extending beyond an end of the first arcuate piece and an end of the second arcuate piece. The first arcuate piece has an opposite end extending beyond an opposite end of the third arcuate piece. The second arcuate piece has an opposite end extending beyond the opposite end of the third arcuate piece. FIG. 7a shows the sensor 11 has three arcuate pieces layered to form each portion of the sensor 11. FIG. 7b shows the sensor 11 in the open position. The end 78 of third piece of the first portion extends beyond the ends of the first and second arcuate pieces of the first portion. The second portion of the sensor 11 is similarly configured. FIG. 7c shows sensor 11 in the closed position. The end 78 of the first portion inserts into the space between the opposite ends of the first and second arcuate pieces of the second portion.

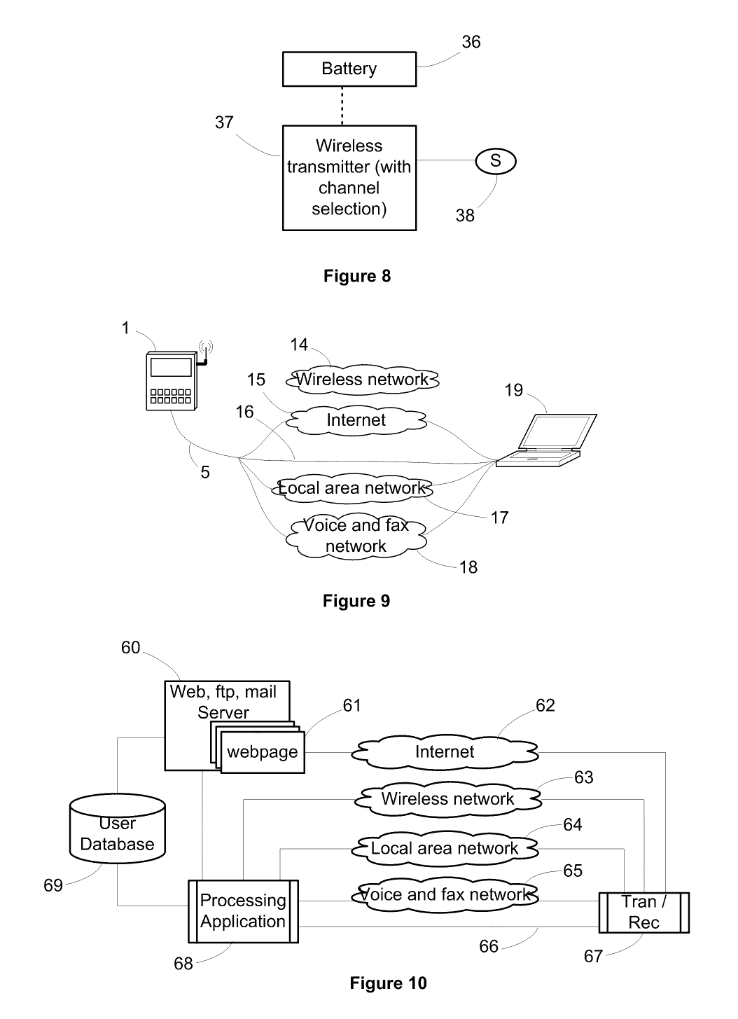

Referring to FIG. 8, there is shown a schematic diagram of the wireless temperature sensor 8 of FIG. 1. The temperature sensor 8 has a small battery 36 with an ultra-low power 2.5 GHz transmitter 37 connected to the analog sensor 38. Different wireless channels are devised to accommodate concurrent use of multiple sensors. In contrast, the wired temperature sensor 7 shown in FIG. 1 has a semiconductor analog device connected to the logging unit 1 via line 3. Wire temperature sensors can be placed inside the building structure 9 at the air intake of each heating and cooling units and in the shade outside the building structure 9.

Referring to FIG. 9, there is shown a schematic diagram of the connection channels between the processing unit 19 and the logging unit 1. The wireless networks 14, Internet 15, Local Area Network 17, and Voice and Fax Networks 18 can relay the data packets between the processing unit 19 and the logging unit 1. Direct line connection 16 also constitutes a valid communication channel. Only one of these channels is active at any moment. In FIG. 9, the processing unit 19 is a laptop computer.

Referring to FIG. 10, there is shown a schematic diagram of the processing unit 19 that connects to the logging unit 1 via wireless network 63, phone landline 65, dedicated lines 66 (such as but not limited to RS232 and USB), the Internet 62, or local area network 64 to. The connection between the processing unit 19 and the logging unit 1 allows: (a) update of the logging unit 1 embedded logging algorithm and (b) receipt of the collected readings. The processing unit 19 has a web server 60, relational database labeled as User Database 69 and referred to herein simply as “database”, and processing application 68 that runs on a computer-based platform in co-located or distributed topology. The web server 60 contains web pages 61 and File Transfer Protocol (ftp) server 60. A web page is the entry point for the user to edit the information about the monitored building 9 and its characteristics, such as total estimated size of windows and external walls of the building 9, total surface area of the building 9, previous electric utility bill meter reading, cost per kilowatt, and the number of heating and cooling systems for the areas assigned. The webpage is protected by a password chosen by the user. A report is published on the web page. The ftp server is serviced by the web server and used for the file transfer if the logging unit 1 is connected to the Internet. The email server is collocated with the web server and is responsible for sending reports and various messages to users. The database records are created to store users' information provided through the web page in the database 69. Data files are cross-referenced by the user identification number and stored in the database 69. The database 69 receives the results of the processing application 68, including the final report.

The processing application 68 of the processing unit 19 communicates with the logging unit 1, receives the data files, stores the data files in the database 69, and processes the data files. The processing application is a sophisticated long operation that is executed in multiple processes. The processes are: 1) the Transmit and Receive process, 2) the Data Correction process, 3) the Thermal Characteristic process, 4) the Heating and Cooling System Analysis process, 5) the Benchmarking process, 6) the Energy Use Profile process, 7) the Warning process, 8) the Alternative Energy process, and 9) the Reporting process. Each process has s start and end point where the end of one process connects to the start of the next.

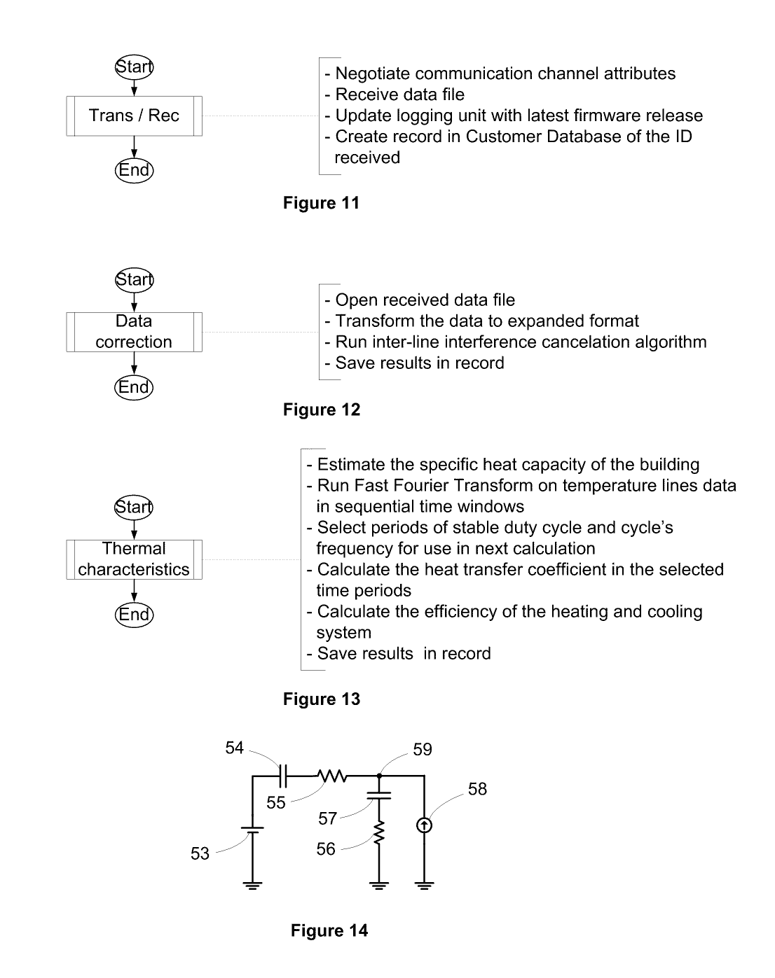

Referring to FIG. 11, there is shown a process flow diagram for the Transmit and Receive process, which is responsible for negotiating the attributes of the communication channel(s) between the logging unit 1 and the processing unit 19, receiving the data file from the logging unit 1, updating the logging unit 1 with the latest firmware software release, creating a record in the database, and linking the record to the received data file. At the end of the Transmit and Receive process, the data file is recorded in the database.

Referring to FIG. 12, there is shown a process flow diagram for the Data Correction process of the processing unit 19, which starts after the Transmit and Receive process has ended. The Data Correction process is responsible for reviewing the data file received, expanding the compressed data format, and running an inter-line interference cancellation algorithm so as to remove any inter-line interference caused by the proximity of the plurality of sensors and wire lines in the electric connection panels, that can corrupt the readings. At the end of the Data Correction process, the results are saved in the database.

Referring to FIG. 13, there is shown a process flow diagram for the Thermal Characteristic process of the processing unit 19, which is responsible for identifying the temperature reading data, calculating the composite specific heat capacity (SHC) and heat transfer coefficient (HTC) of the building structure, and calculating the efficiency rating of the heating and cooling system.

Referring to FIG. 14, there is shown an electrical diagram of a thermal model for the system 100. Each zone i of the building structure 9 has a composite heat transfer coefficient that is represented by a resistance 55, Rₛⁱ, in series with a capacitance 54, Cₛⁱ. Rₛⁱ depends of the external walls, roof, foundation insulation factors, the glass windows, and the actual air flow or infiltration between the inside and outside of zone i of the building 9. The composite specific heat capacity of the building 9 is represented by a capacitance 57, Cᵥⁱ, in series with a resistance 56, Rᵥⁱ. Cᵥⁱ depends of the air volume inside the building and the amount and type of furniture inside the building. The capacitive load of the building's Cₛⁱ external shell is negligible compared to Cᵥⁱ. Rᵥⁱ represents the resistance for heat transfer within the volume of the building that largely depends on the air heat transfer and the air circulation. For 1st degree simplification of the calculation, the Cₛⁱ and Rᵥⁱ are discarded because of their minimal order of influence. The differential measured Tᵢₙⁱ 59 is the inside zone i and the differential measured Tₒᵤₜ 53 is the temperature outside the building 9.

The sum of multiple sources of heat is shown by the equation below:

Q_{c}ⁱ+Qₑⁱ+Q_{hc}ⁱ+Qᵣⁱ+Q₀ⁱ (1)

where “i” is the index of the zone—the independently-controlled heated and cooled area in the building structure 9. For all the zones, Q_{c}ⁱ is the sum of multiple of sources of heat. Qₑⁱ is the heat generated by the electrical appliances inside the building. Q_{hc}ⁱ, is the heat generated by the heating and cooling system. Qᵣⁱ is the heat generated by direct sunlight on the surface of the building. Q₀ⁱ is the heat generated by the occupant of the building and other heat sources. Qₑⁱ is calculated by the following equation:

$${Q}_{e}^{i} = {\sum }_{n = 1}^{M} {I}_{n}^{i} {E}_{n}^{i} Vdt \qquad ( 2 )$$

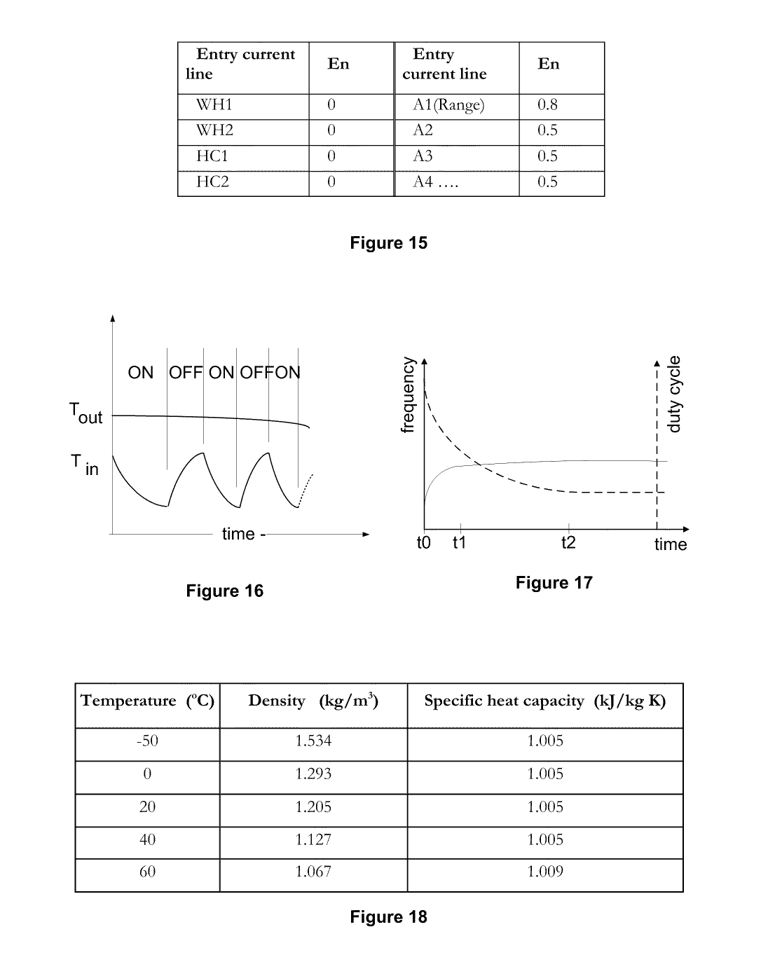

Iₙⁱ is the current from input “n” associated with the area “””. Eₙⁱ is the heat-release factor for the type of input n. “V” is the line voltage. “dt” is the time lapse. The factors Eₙⁱ are assigned to each category of current lines per the table in FIG. 15. In FIG. 15, Eₙⁱ is determined by the type of device associated with a current line as opposed to the quality of the specific device.

Referring to FIG. 16, there is shown a graph of the inside and outside temperature signals as a function of time, correlated with the operating cycle of the heating and cooling system of the building 9. “ON” represents the status of the heating and cooling system operating, while the “OFF” represents the off state of the heating and cooling system.

Q_{hc}ⁱ is null during the off cycle of the heating and cooling system of the building 9. Qᵣⁱ is null during the night. The equation governing the thermal model is written below:

$${T}_{in}^{i} - {T}_{out} = {R}_{s}^{i} ( {C}_{v}^{i} \frac{d {T}_{in}^{i}}{d t} + {Q}_{e}^{i} ) \qquad ( 3 )$$

Tᵢₙⁱ is the temperature of the zone i. Tₒᵤₜ is the temperature outside the building.

The duty cycle of the “on” and “off” operation cycles of the heating and cooling system is calculated by the following equation:

$${D}^{i} = \frac{Δ {t}_{on}^{i}}{Δ {t}_{on}^{i} + Δ {t}_{off}^{i}} \qquad ( 4 )$$

The cycles' frequency increases slightly because the of the negligible effect of Rᵥⁱ that delays the charging of the capacitive load, Cᵥⁱ. The cycles' frequency and the duty cycle tend to stabilize after a couple of cycles within a constant setting of temperature controlled heating and cooling operation and constant external temperature. This is a characteristic of normal heating and cooling operation.

Referring to FIG. 17, there is shown a graph for the frequency of the cycle versus time. The point in time t1 where the cycles' frequency tends to stabilize and t2 points to the duty cycle stabilizing when the capacitive load Cᵥⁱ is becoming homogeneously charged and temperature in building becomes uniform. Using the air density's temperature table in FIG. 18, the thermal characteristic algorithm first estimate is calculated at temperature Tᵢₙⁱ in the following equation:

Cᵥⁱ=PⁱCⁱₚVⁱ (5)

The air volume, Vⁱ, of the area, which is estimated by the surface multiplied by the ceiling height, is served by the heating and cooling system number i. The temperature is sensed by the sensor Ti, Cⁱₚ is the specific heat capacity of air in zone I, and Pⁱ is the density of air in zone i. The total composite specific heat capacity of the building is shown in Equation 6 below:

$${C}_{v} = {\sum }_{i = 1}^{m} {C}_{v}^{i} \qquad ( 6 )$$

In Equation 6, “m” is the total number of independently-controlled and zoned heated and cooled areas of the building 9.

The Thermal Characteristics process divides the twenty-four hours of a day into six windows: 1) 12 am to 4 am, 2) 4 am to 8 am, 3) 8 am to 12 pm, 4) 12 pm to 4 pm, 5) 4 pm to 8 pm, and 6)6) 8 pm to 12 am. The Thermal Characteristics process calculates the fast Fourier transformation on each window and each temperature line. The process selects the windows, Wj, that contain frequency envelops fitting predefined set shape/template. The use of a defined template eliminates the need to discard the third and fourth windows of time that fall into the sunny periods of the day because of the sun exposure. These windows (of total count 1) identify the presence of stabilized cycling operation of the heating and cooling systems.

For each of the selected windows, Wj, the composite heat transfer coefficient is calculated for each zone i of the building per the following equations:

$$\begin{matrix}{R}_{s}^{i} = \frac{1}{l} {\sum }_{j = 1}^{l} {R}_{s}^{{i}_{j}} & ( 7 ) \\ {R}_{s}^{{i}_{j}} = \frac{1}{k} {\sum }_{x = 1}^{k} \frac{{T}_{in}^{{i}_{j}} - {T}_{out}}{{C}_{v}^{i} \frac{d {T}_{in}^{i}}{d t} + {Q}_{e}^{j}} & ( 8 )\end{matrix}$$

where j is the index of the window Wj, k is the total number of samples x collected in window Wj, and

$$\frac{d {T}_{in}^{i}}{d t}$$

is the increment of the temperature of zone i at each sample x.

Equations 7 and 8 are calculated during the off cycle of the heating and cooling system. The overall composite heat transfer coefficient is the average over all the areas calculated in the following equation:

$${R}_{s} = \frac{1}{m} {\sum }_{i = 1}^{m} {R}_{s}^{i} \qquad ( 9 )$$

Equation 10 is the efficiency of the HVAC system as used in the building:

$${E}^{i} = \frac{1}{l} {\sum }_{j = 1}^{l} \frac{{I}_{j}^{i} V}{{Q}_{bc , j}} \qquad ( 10 )$$

Q_{hc,j} is the heat value calculated back from the model equation (Equation 3) in each selected window, “j”, during the on cycle of the heat and cooling system. Iⁱⱼ is the current sensed for the heating and cooling system of zone i. At the end of the Thermal Characteristics process the results are saved in the database 69.

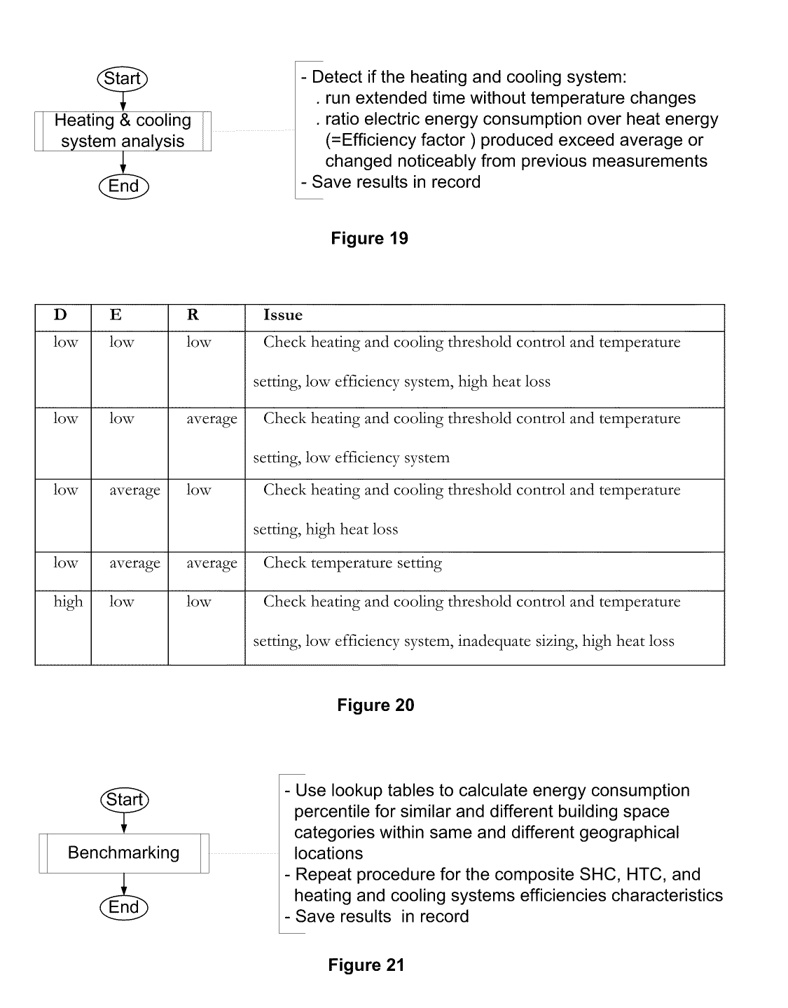

Referring to FIG. 19, there is shown a process flow diagram for the Heating and Cooling System Analysis process that correlates the heating and cooling units' electric energy consumption with the specific heat capacity and heat transfer coefficients so as to deduce unbalances in the energy equations, which indicate or negate the fitness and/or defect of the units for the operation.

Referring to FIG. 20, there is shown a table that showing a part of a lookup table for issue-identification selection. Column D is for the Duty Cycle value. Column E is for the Efficiency rating of the heating and cooling system. Column R is for the actual composite heat transfer coefficient of the building 9. The issue column is for the possible issue resulting of the combination of the three factors D, E, and R. The table is much longer and contains all other possible combinations of D, E, and R. The Low, Average, and High levels are specific to each column and predetermined in advance. FIG. 20 shows the use of the efficiency factors, Eⁱ, and the duty cycles, Dⁱ, calculated in the Thermal Characteristics process with lookup tables to identify possible issues. At the end of the Heating and Cooling System Analysis process the results are saved in the database.

Referring to FIG. 21, there is shown a process flow diagram for the Benchmarking process responsible for benchmarking the energy use values, the specific heat capacity, the heat transfer coefficient, the efficiency factors Eⁱ versus same factors for similar building size in geographical areas, to generate recommendations for improvements corrective actions such as attic additional insulation, tinting or replacing windows, changing heat and cooling system.

Referring to FIG. 22, there is shown an excerpt of the benchmarking section of the report generated in Reporting process and displaying the comparative results of the energy usage compared to similar building area in the same selected U.S. state, to the nationwide average, to all areas, and to the nationwide heating and cooling efficiency parameters. Each mark is indicated on a gradient scale with an automatically inserted comment below. At the end of the Benchmarking process, the results are saved in the database 69.

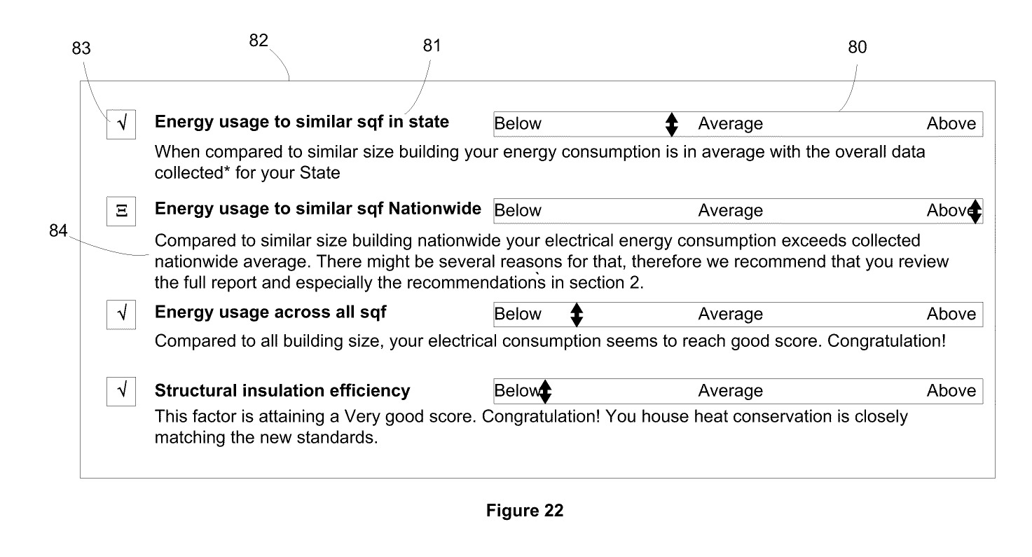

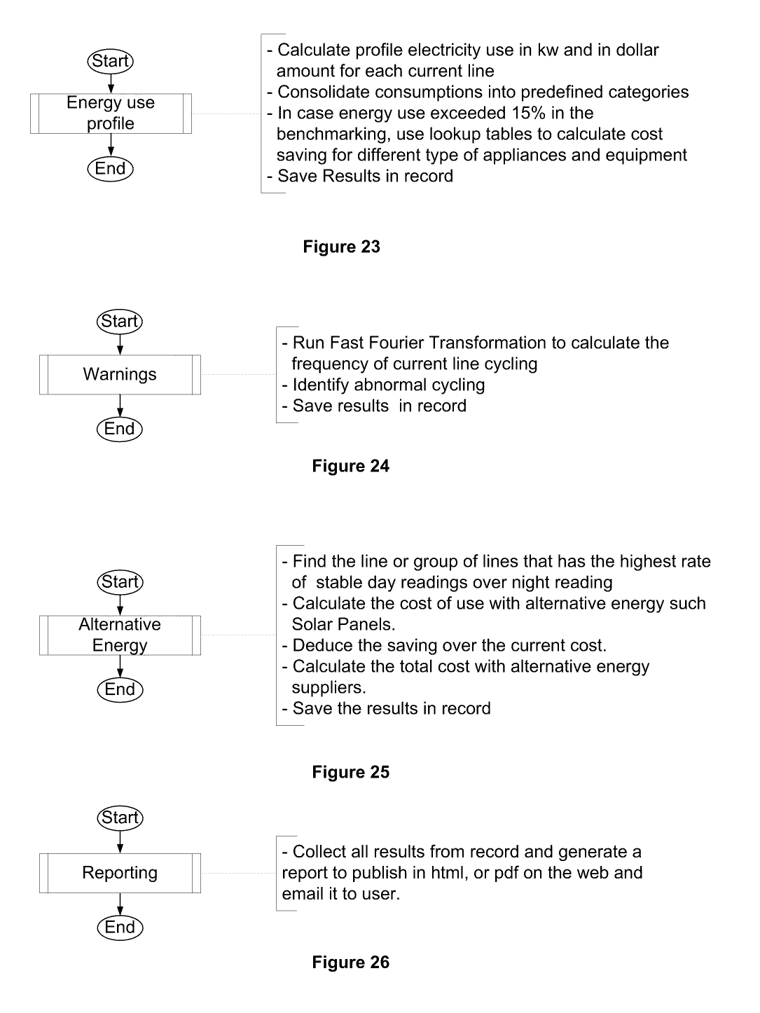

Referring to FIG. 23, there is shown a process flow diagram for the Energy Use Profile process responsible for correlating electricity usage over a moving time window to characterize the usage profile and classifying the consuming devices by category so as to estimate the current electricity usage and the possible alternatives to identify the cost saving for switching categories. An example of this is switching the light bulb types, switching electric switches to occupant detection activated electric switches, and switching household appliances from those currently used to Energy Star® rated or less-consuming units. At the end of the Energy Use Profile process, the results are saved in the database 69.

Referring to FIG. 24, there is shown a process flow diagram for the Warning process responsible for identifying abnormal operation of consuming devices such abnormal high consumption or near tripping breakers, operation during unexpected or abnormal periods, excessive cycling. At the end of the Warning process the results are saved in the database.

Referring to FIG. 25, there is shown a process flow diagram for the Alternative Energy process responsible for identifying the most adapted electric supply line or group of lines to be supplied with alternative energy such solar energy with minimum need of electric energy accumulation such batteries. At the end of the Alternative Energy process the results are saved in the database.

Referring to FIG. 26, there is shown a process flow diagram for the Reporting process responsible for creating a comprehensive report detailing all the results stored in the database linked to the received data file and publishes it on a website in the user profile webpage and or email it to specific address.

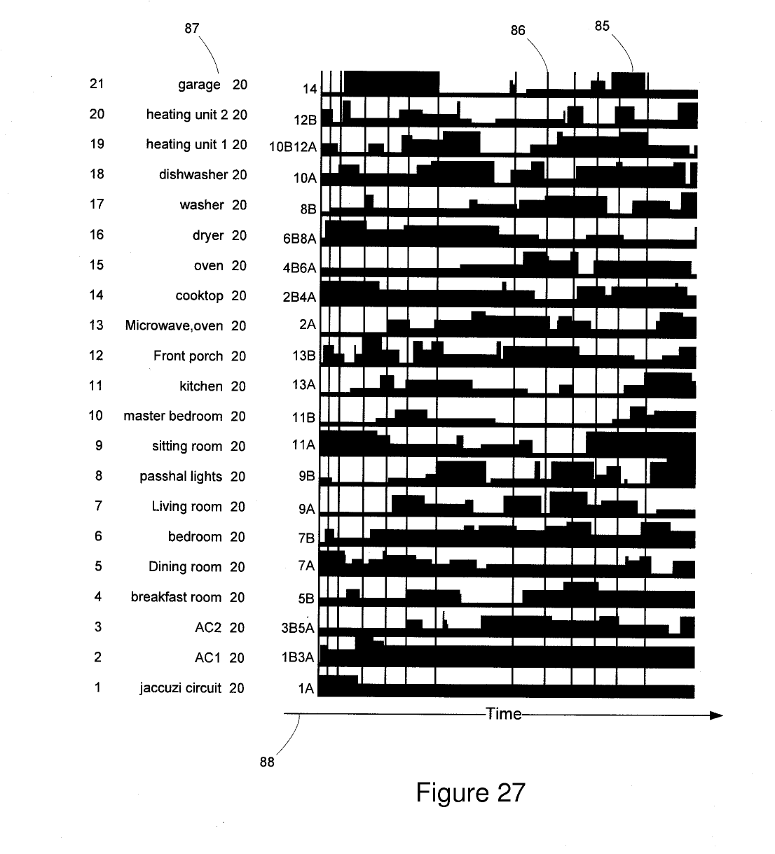

Referring to FIG. 27, there is shown a process flow diagram for a section of the report generated by the Reporting process. Each horizontal section starts with a header 87 indicating the measured area with specific identifications collected from the electric panel. Each horizontal section contains a variable bold lines 85 that represents the value of the measured current or energy consumed in that electric branch of the building. The thicker is the line the more is the electric consummation. The vertical lines 86 delimit the time windows indicated by the time line 88.

The foregoing description is illustrative and explanatory of the disclosed embodiments. Various changes can be made to the embodiments without departing from the spirit and scope of the invention. Therefore, the invention should be limited only by the following claims and their legal equivalents.

I claim:

1. A method for comprehensive energy measurement and analysis of a building comprising:
analyzing a thermal characteristic of the building;
analyzing an efficiency of an HVAC system of the building; and
tracking an energy usage of at least one consuming device associated with the building.

2. The method of claim 1, said step of analyzing a thermal characteristic comprising:
recording a inside temperature of the building;
recording an outside temperature of the building; and
calculating the thermal characteristic using the recorded inside temperature of the building and the recorded outside temperature of the building.

3. The method of claim 2, said step of calculating comprising:
calculating a composite specific heat capacity of the building;
calculating a heat transfer coefficient of the building structure.

4. The method of claim 1, said step of analyzing an efficiency of an HVAC comprising:
recording an electric current use of the HVAC system;
recording an inside temperature of the building;
recording an outside temperature of the building; and
calculating the efficiency using the recorded inside temperature of the building and the recorded outside temperature of the building.

5. The method of claim 4, said step of calculating comprising:
calculating a heat transfer of the HVAC system; and
correlating an energy consumption of the HVAC system with the heat transfer of the HVAC system.

6. The method of claim 1, further comprising:
generating an electric energy usage profile for the consuming device associated with the building.

7. The method of claim 6, said step of generating comprising:
executing an energy use profile process;
executing a warning process; and
executing an alternative energy process.

8. The method of claim 7, said step of executing an energy use profile process comprising:
correlating electricity usage over a moving time window;
classifying the consuming device in one of a plurality of categories;
estimating a current electricity usage; and
identifying alternatives for cost savings for each of the plurality of categories.

9. The method of claim 7, said step of executing a warning process comprising:
identifying abnormal operation of the consuming device; and
saving an identification of abnormal operation in a database.

10. The method of claim 7, said step of executing an alternative energy process comprising:
identifying an adapted electric supply line to be supplied with alternative energy; and
saving an identification of adapted electric supply line in a database.

11. The method of claim 1, further comprising:
benchmarking the thermal characteristic of the building with a characteristic of another building;
negotiating an attribute of a communication channel between a logging unit and a processing unit;
receiving a data file from the logging unit;
creating a record in a database;
linking the record to the received data file; and
recording the data file in the database.

12. An apparatus comprising:
a plurality of sensors;
a logging unit in communication with said plurality of sensors; and
a processing unit in communication with said logging unit, said processing unit suitable for calculating at least one thermal characteristic of a building, said processing unit suitable for calculating at least one efficiency of an HVAC system associated with said building, said processing unit suitable for analyzing the thermal characteristic and the efficiency, said processing unit suitable for reporting the analyzed thermal characteristic and the efficiency.

13. The apparatus of claim 12, said logging unit comprising:
an LCD screen;
a battery connected to said LCD screen;
a flash memory connected to said battery;
a socket suitable for connecting to said plurality of sensors;
a communication controller connected to said flash memory;
a micro controller connected to said LCD screen and said communication controller and said flash memory and said socket; and
a plurality of pushbuttons connected to said micro controller.

14. The apparatus of claim 12, said plurality of sensors comprising:
at least one temperature sensor positioned inside the building;
at least one temperature sensor positioned outside the building; and
at least one current sensor positioned on at least one electric wire of the building.

15. The apparatus of claim 12, said processing unit comprising:
a database;
a processing application connected to said database;
a server connected to said database and to said processing application; and
a transceiver connected to said processing application and to said server.

16. The apparatus of claim 15, said processing application comprising:
a transceiving process suitable for transmitting and receiving data packets between said logging unit and said processing unit;
a data correction process suitable for correcting data files of said data packets;
a thermal characteristics process suitable for calculating a specific heat capacity and a heat transfer coefficient;
an analysis process suitable for creating a ratio of electric energy consumption;
a benchmarking process suitable for benchmarking the thermal characteristic of the building;
an energy-use process suitable for providing a profile of energy usage in the building;
a warning process suitable for identifying abnormal operation of at least one consuming device;
an alternative-energy process suitable for identifying a use for alternative energy; and
a reporting process suitable for creating a comprehensive report.

17. The apparatus of claim 16, said energy-use process suitable for providing a profile of energy usage of the consuming device associated with the building.

18. A current sensor comprising:
a hinged bracket having a first portion pivotally connected to a second portion, each of said first portion and said second portion comprising:
a first arcuate piece;
a second arcuate piece spaced from said first arcuate piece; and
a third arcuate piece positioned between said first arcuate piece and said second arcuate piece, said third arcuate piece having an end extending beyond an end of said first arcuate piece and an end of said second arcuate piece, said first arcuate piece having an opposite end extending beyond an opposite end of said third arcuate piece, said second arcuate piece having an opposite end extending beyond said opposite end of said third arcuate piece; and
a coiled wire wrapped around said hinged bracket.

19. A processing application for an energy monitoring and analysis system of a building, the processing application comprising:
a thermal characteristics process suitable for calculating at least one specific heat capacity of a building and at least one heat transfer coefficient of the building;
an analyzing process suitable for calculating a heat transfer and an energy consumption of at least a portion of an HVAC system associated with the building; and
an energy-use process suitable for generating a profile of energy usage of at least one consuming device associated with the building.

20. The processing application of claim 19, said thermal characteristics process utilizing an outside temperature of the building, said analyzing process utilizing the outside temperature of the building.
